(19) United States
(12) Patent Application Publication
(10) Pub. No.: US 2026/0215293 A1
(43) Pub. Date: Jul. 23, 2026

(54) POWER MODULE WITH OVERMOULDING

(71) Applicant: VALEO ELECTRIFICATION, Creteil Cedex (FR)

(72) Inventors: Gabriel KOPP, Creteil Cedex (FR); Laurent MASSOL, Creteil Cedex (FR)

(73) Assignee: VALEO ELECTRIFICATION, Creteil Cedex (FR)

(21) Appl. No.: 19/143,200

(22) PCT Filed: Dec. 27, 2023
(86) PCT No.: PCT/EP2023/087866

§ 371 Date: Jun. 25, 2025

(30) Foreign Application Priority Data
Dec. 27, 2022 (FR) FR2214566

(51) Int. Cl. H10W 70/40; H10W 70/04; H10W 74/01; H10W 74/10; H10W 90/00; H10W 90/10

(52) U.S. Cl. CPC H10W 70/424; H10W 70/048; H10W 70/411; H10W 74/01; H10W 74/114; H10W 90/811; H10W 90/10; H10W 90/756

(57) ABSTRACT

A power module including electrical conductors, each of which has an upper face, at least one semiconductor component attached to the upper face of one of the conductors, and an overmoulding that extends over at least one portion of the upper face of each of the conductors. At least one of the upper faces has, in its overmoulded portion, at least one attachment groove which is filled by the overmoulding and passes through a point (P) on the upper face that experiences a mechanical stress (T) as a result of the overmoulding. The attachment groove forming, at this point (P), at a predefined temperature, an angle with the mechanical stress (T) of between 60° and 120°, preferably between 85° and 95°, and more preferably 90°.

### TECHNICAL FIELD OF THE INVENTION

The present invention relates to a power module with overmolding, a voltage converter including such a power module, an electric drive device including such a voltage converter, a mobility vehicle including such a power module or such an electric drive device, as well as a method for manufacturing a power module.

A mobility vehicle is for example a motorized land vehicle, a train, an aircraft or even a drone. A motorized land vehicle is for example a motor vehicle, a motorbike, a motorized bicycle or even a motorized wheelchair.

### TECHNOLOGICAL BACKGROUND

The prior art discloses a power module including:
electrical conductors each having an upper face;
at least one semiconductor component fastened to the upper face of one of the conductors; and
an overmolding extending over at least a portion of the upper face of each of the conductors.

During the manufacture of such a power module, and in particular during overmolding, epoxy resin is generally injected at high temperature onto the previously heated copper conductors.

Upward bowing has been noted as the assembly cools, resulting in mechanical shear stresses between the conductors and the overmolding.

Mechanical adhesion between conductors and the overmolding is weak to facilitate wiring, and chemical adhesion is also weak, resulting only from Van der Waals chemical bonds, which are easily weakened by impurities (for example, one or more of chlorine, tin, silicone (PDMS)) penetrating between the conductors and the overmolding.

Thus, these mechanical stresses pose a significant risk of delaminating the overmolding, thereby reducing the reliability of the power module.

It may thus be desirable to provide a power module which makes it possible to eliminate at least some of the aforementioned problems and stresses.

### SUMMARY OF THE INVENTION

Therefore, a power module including the following is proposed:
electrical conductors each having an upper face;
at least one semiconductor component fastened to the upper face of one of the conductors; and
an overmolding extending over at least a portion of the upper face of each of the conductors; characterized in that at least one of the upper faces has, in its overmolded portion, at least one attachment groove which is filled by the overmolding and passes through a point on the upper face that is subjected to a mechanical stress by the overmolding, the attachment groove forming, at this point, at a predefined temperature, an angle with the mechanical stress of between 60° and 120°, preferably between 85° and 95°, and more preferably 90°.

Thus, thanks to the invention, the attachment grooves offer good adhesion between the conductors and the overmolding, reducing the risk of delamination.

The invention may further include one or more of the following optional features, according to any technically feasible combination.

Optionally, the mechanical stress results at least in part from the different coefficients of thermal expansion of the conductor carrying the attachment groove and the overmolding.

Also optionally, the predefined temperature is between −50° C. and 200° C., for example the predefined temperature is the ambient temperature, for example 25° C.

Also optionally, the predefined temperature is the temperature at the point of the upper face subjected to the mechanical stress resulting from a temperature gradient between one or more hot spots of the power module and the remainder of the structure of the power module, for example the hot spot may be the semiconductor component fastened to the upper face of one of the conductors of the power module at its operating temperature, said operating temperature being for example 175° C. The hot spot is thus located at the location of the semiconductor component.

Again by way of example, said hot spots may be the semiconductor components of the power module at their operating temperature, said operating temperature being for example 175° C. The hot spots are thus located at the location of the semiconductor components.

The operating temperature is by definition the usual operating temperature of the semiconductor component or components of the power module, this usual temperature being the normal operating temperature of the semiconductor component or components, as defined for example by the data sheet of the semiconductor component or components or by the data sheet of the power module or else by operating tests on the power module.

Also optionally, the attachment groove is located at least 0.3 mm from the semiconductor component or components.

Also optionally, the attachment groove is straight.

Also optionally, the upper faces of the conductors are flat and coplanar.

Also optionally, the conductors have thicknesses perpendicular to their upper faces of more than 1 mm, respectively.

Also optionally, the overmolding is made of epoxy resin.

Also optionally, the conductors are made of copper.

Also optionally, the attachment groove has a length and a width perpendicular to its length of at most 5% of its length.

Also optionally, the attachment groove has a bottom and two side walls extending from the bottom to the upper face of the conductor carrying the attachment groove, the two side walls being perpendicular to the upper face.

Also optionally, the attachment groove has a bottom and two side walls extending from the bottom to the upper face of the conductor carrying the attachment groove, one side wall of the side walls being perpendicular to the upper face and the other side wall being oblique with respect to the upper face.

Also optionally, the attachment groove has a bottom and two side walls extending from the bottom to the upper face of the conductor carrying the attachment groove, the two side walls being oblique with respect to the upper face.

Also optionally, the oblique side wall or the oblique side walls form, with the upper face, an angle of between 30° and 60° with the upper face.

Also optionally, the attachment groove has a depth and a width on the upper face of between 90% and 110% of the depth.

Also optionally, the power module includes two parallel attachment grooves on the upper face of one electrical conductor without any other attachment grooves between them.

Also optionally, the power module includes two parallel attachment grooves on the upper face of one electrical conductor without any other attachment grooves between them, the projection of one of the two grooves in the direction orthogonal to its length along the upper surface of the conductor intersects the straight line defined by the other of the two grooves and the other of the two grooves.

Also optionally, each of the two parallel attachment grooves has a depth and a width on the upper face, these two parallel attachment grooves being separated from each other by a distance greater than five times the depth and/or the width of each of the two.

Also optionally, the power module includes two attachment grooves on the upper face of one electrical conductor, perpendicular to each other.

Also optionally, the power module includes two attachment grooves on the upper face of one electrical conductor, said attachment grooves each passing through a point located along one isostress line.

The isostress lines therefore represent lines where the mechanical stresses are of equal intensity.

Preferably, the isostress lines represent lines where the mechanical stresses of equal intensity are exerted perpendicular to said isostress lines.

Also optionally, the power module includes two attachment grooves on the upper face of one electrical conductor, said attachment grooves each passing through a point subjected to a mechanical stress of equal intensity.

Also optionally, the power module includes several semiconductor components implementing a switching arm.

A voltage converter including at least one power module according to the invention, and a system for controlling the semiconductor component or components of the power module or modules are also proposed.

An electric drive device including a voltage converter according to the invention, designed to perform AC-DC power conversion, and an electric machine connected to the voltage converter are also proposed.

A mobility vehicle including a power module according to the invention, or a voltage converter according to the invention, or an electric drive device according to the invention is also proposed.

A method for manufacturing a power module with electrical conductors, of which each has an upper face, at least one semiconductor component fastened to the upper face of one of the conductors, and an overmolding that extends over at least a portion of the upper face of each of the conductors is also proposed, the method including:
evaluating, in the power module to be manufactured, a mechanical stress exerted by the overmolding at a point on the upper face of one of the conductors; making at least one attachment groove on the upper face, the attachment groove passing through the point where the mechanical stress has been evaluated and forming at this point an angle with the mechanical stress of between 60° and 120°, preferably between 85° and 95°;
fastening the semiconductor component or components (306) to the upper face of one of the conductors; and
overmolding the conductors and in particular at least a portion of the upper face where the attachment groove has been made, so as to fill the attachment groove with the overmolding.

Optionally, the attachment groove is located at least 0.3 mm from the semiconductor component or components.

Optionally, the attachment groove is made by stamping.

### BRIEF DESCRIPTION OF THE FIGURES

The invention will be better understood on reading the following description, which is given solely by way of example and with reference to the appended drawings, in which:

FIG. 1 is a schematic view of a motorized land vehicle in which the invention may be implemented,

FIG. 2 is an electrical diagram of a voltage converter of the vehicle in FIG. 1,

FIG. 3 is a simplified cross-sectional side view of a power module of the voltage converter in FIG. 2,

FIG. 4 is a top view of the power module, with a transparent overmolding and excluding the wirings of the semiconductor components of the power module,

FIG. 5 is a top view of an attachment groove provided on an upper face of an electrical conductor of the power module,

FIG. 6 is a simplified cross-sectional side view of the attachment groove, illustrating a first possible profile,

FIG. 7 is a simplified cross-sectional side view of the attachment groove, illustrating a second possible profile,

FIG. 8 is a simplified cross-sectional side view of the attachment groove, illustrating a third possible profile,

FIG. 9 is a simplified cross-sectional side view of two successive parallel grooves,

FIG. 10 is a block diagram illustrating the steps of a method for manufacturing the power module,

FIG. 11 is a top view of a stamped plate, during the method in FIG. 10,

FIG. 12 is a top view of the plate after cutting, as provided for in the method in FIG. 10,

FIG. 13 is a view similar to the view in FIG. 4, with a different layout of the attachment grooves,

FIG. 14 is a side view illustrating a bowing due to shrinkage of the overmolding, and

FIG. 15 is a side view illustrating a bowing due to a difference in the coefficients of thermal expansion.

### DETAILED DESCRIPTION OF THE INVENTION

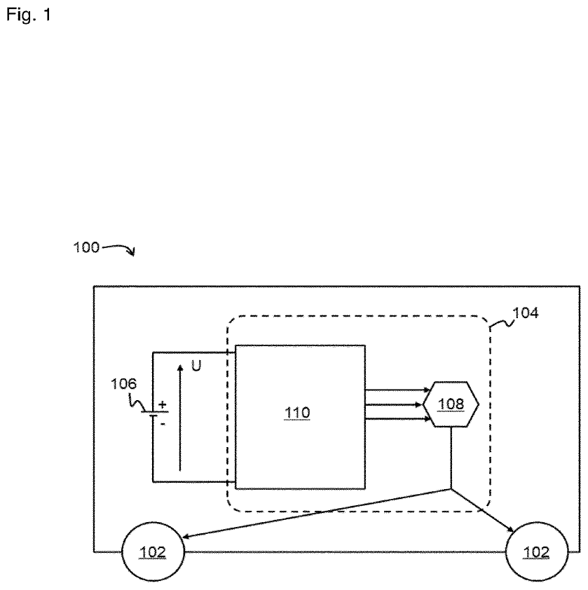

A motorized land vehicle 100 in which the invention may be implemented is described below with reference to FIG. 1.

The vehicle 100 includes one or more drive wheels 102 designed to set the vehicle 100 in motion.

In order to drive the drive wheel or wheels 102, the mobility vehicle 100 further comprises an electric drive device 104 and a DC voltage source 106, such as a battery, designed to power the electric drive device 104 electrically.

The electric drive device 104 includes an electric machine 108, in particular a polyphase machine, for example a three-phase machine, connected to the drive wheels 102 to drive the latter. The electric drive device 104 further includes an AC-DC electric voltage converter 110 connected between the DC voltage source 106 and the electric machine 108. The electric voltage converter 110 is configured to transfer electric power between the DC voltage source 106 and the electric machine 108. For example, the AC-DC converter 110 is configured to operate as an inverter to transfer electric power from the DC voltage source 106 to the electric machine 108 operating as an electric motor. The AC-DC converter 110 may also be configured to operate as a rectifier to transfer electric power from the electric machine 108 operating as an electric generator to the DC voltage source 106, for example to recharge the latter.

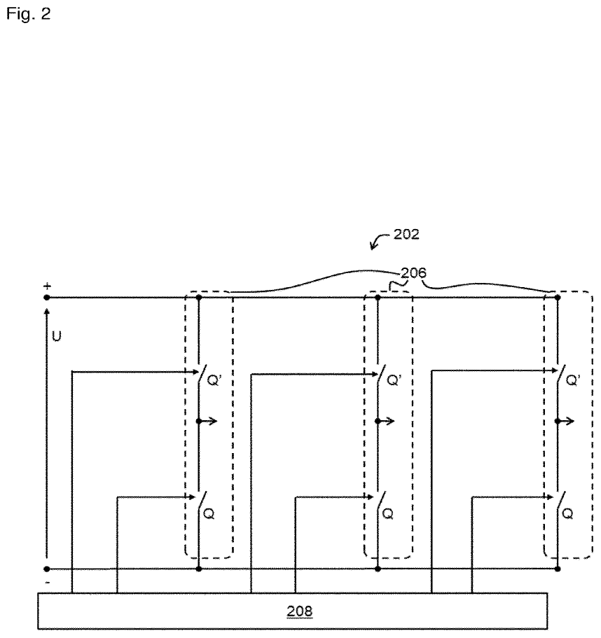

With reference to FIG. 2, the electric voltage converter 110 comprises a switching circuit 202 with low-side switches Q and high-side switches Q′. The switches Q, Q′ are semiconductor switches, for example transistors such as metal oxide semiconductor field effect transistors (MOSFET) or silicon metal oxide semiconductor field effect transistors (Si MOSFET) or silicon carbide metal oxide semiconductor field effect transistors (SIC MOSFET) or insulated gate bipolar transistors (IGBT) or gallium nitride field effect transistors (GaN FET).

The switching circuit 202 for example includes at least one switching arm 206, and for example the same number of switching arms 206 as stator phases in the electric machine 108. Each switching arm 206 comprises a high-side switch Q′ and a low-side switch Q connected to each other at a midpoint. Each switching arm is connected between terminals +, − of the DC voltage source 106. The midpoint is connected to one of the stator phases of the electric machine 108.

Each switching arm 206 is thus configured to switch between two configurations. In a first configuration, the high-side switch is closed and the low-side switch is open, such that a DC voltage is essentially applied to the midpoint and thus to the stator phase connected thereto. In a second configuration, the high-side switch is open and the low-side switch is closed, such that a zero voltage is applied to the midpoint and therefore to the associated stator phase.

The electric voltage converter 110 further includes a device 208 for controlling the switches Q, Q′ generally via respective drivers (not shown). The control device 208 is for example designed to control the switches Q, Q′ in order to regulate phase currents transmitted to the stator phases from the midpoints.

At least one of the switching arms 206 is for example implemented in a power module.

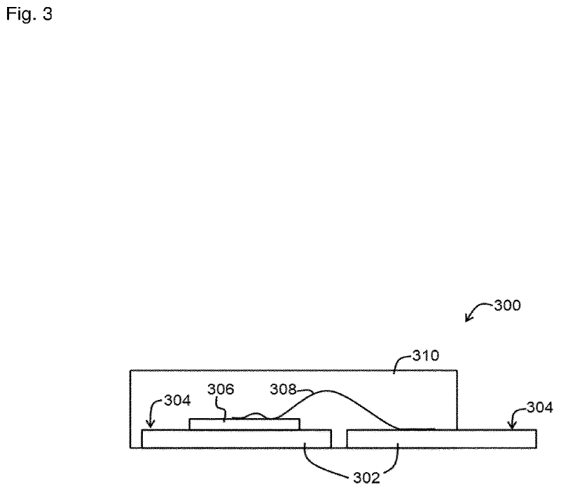

With reference to FIG. 3, the power module, denoted by reference sign 300, includes first of all several electrical conductors 302, for example made of copper.

These conductors 302 are rigid and have an upper face 304. For example, the upper faces 304 are flat and coplanar. The conductors 302 all have for example the same thickness, perpendicular to their upper faces 304. This thickness is preferably more than 1 mm, in order to allow sufficient current to pass through for the power applications. For example, as described below, the conductors 302 are obtained by cutting one initial plate.

The power module 300 further includes at least one semiconductor component 306 forming, for example and at least in part, one of the switches Q, Q′ in FIG. 2. Each semiconductor component 306 is fastened to the upper face 304 of a respective one of the conductors 302. Some conductors 302 may be devoid of a semiconductor component.

The power module 300 further includes wirings 308, for example ribbons or wires, for connecting each semiconductor component to a conductor 302 other than the conductor carrying the semiconductor component.

The power module 300 further includes an overmolding 310 extending over at least a portion of the upper face 304 of each of the conductors 302, in order to coat, in the example described here, each semiconductor component 306 and its wiring 308. The overmolding 310 is for example made of epoxy resin.

Epoxy resin for example has a coefficient of thermal expansion (CTE) of less than or equal to 11 ppm/C and/or a Young's modulus greater than or equal to 18 GPa and/or a volume shrinkage of less than or equal to 0.2%.

The copper of the conductors 302 for example has a CTE greater than or equal to 17 ppm/° C. and/or a Young's modulus greater than or equal to 120 GPa and/or a coefficient of friction with the epoxy resin greater than or equal to 0.3.

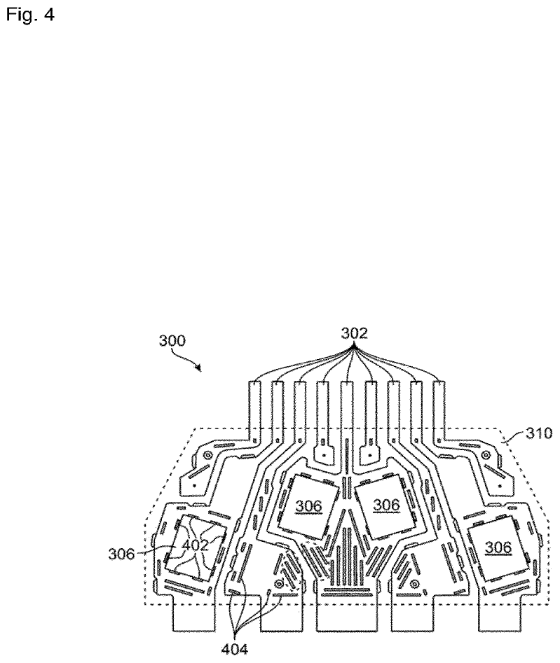

With reference to FIG. 4, the upper faces 304 of the conductors 302 carrying a semiconductor component 306 have confinement grooves 402 around each semiconductor component 306. These confinement grooves 402 are arranged beside the semiconductor components 306 (less than 0.1 mm away from the latter) and are used to position the semiconductor component 306 on the conductor 302 and to prevent the alloy used for brazing from overflowing. This function is provided by the confinement grooves 402 generating a geometric rupture with the upper face 304 of the conductor 302 which clings to the meniscus of the molten alloy during brazing.

For the sake of clarity, the confinement grooves 402 are referenced only for one of the semiconductor components 306.

Moreover, at least one of the upper faces 304 of the conductors 302 has, in its overmolded portion, at least one attachment groove 404 filled by the overmolding 310, the limits of which are illustrated by dotted lines in FIG. 4. For example, as in the example illustrated, all the upper faces 304 of the conductors 302 have several attachment grooves 404. For the sake of clarity, only some are referenced in FIG. 4.

The attachment grooves 404 are distributed on the upper faces and are at least 0.3 mm from each semiconductor component 306.

For example, each attachment groove 404 is straight, i.e. extends over the upper face 304 in a straight line. This makes them easier to make, compared to other shapes.

Moreover, several attachment grooves 404 are preferably parallel to each other, one behind the other in a direction perpendicular to each of them, without any other attachment grooves between them, such as those circled by dotted lines in FIG. 4. In particular, considering two successive grooves in this perpendicular direction, the projection of one of these two successive grooves in the direction orthogonal to its length along the upper surface of the conductor intersects the straight line defined by the other of these two successive grooves and the other of these two successive grooves.

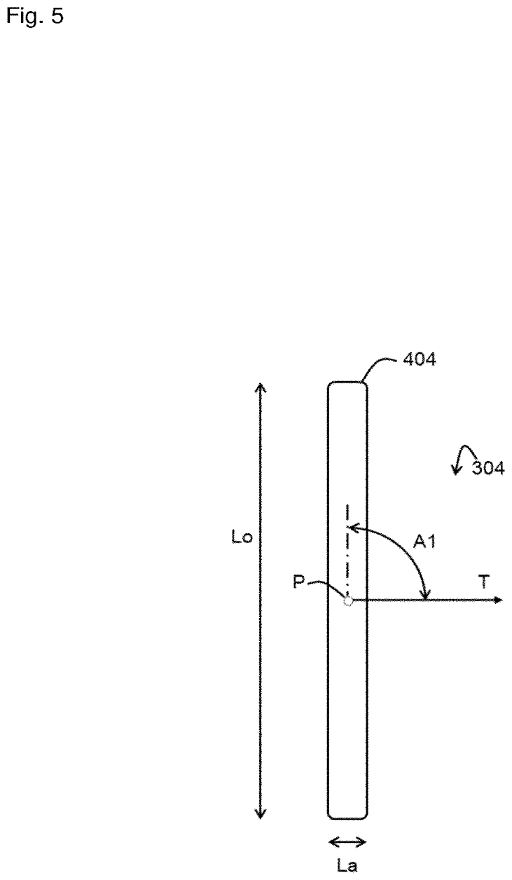

With reference to FIG. 5, each attachment groove 404 passes through a point P of the upper face 304 that is subjected to a mechanical stress T by the overmolding 310. The attachment groove 404 is thus made so that, at this point P, an angle A 1 is formed with the mechanical stress T of 60° to 120°, preferably 85° to 95°, and more preferably 90°. The mechanical stress T considered is that existing at a predefined temperature of the conductor 302 and of the overmolding 310 around the attachment groove 404. This predefined temperature is for example between −50° C. and 200° C., i.e. the usual range of temperatures encountered by the power module, when stopped and in operation. The predefined temperature may differ from one attachment groove 404 to another. For example, the orientation of some or all attachment grooves 404 may be defined with a predefined uniform temperature range, for example 25° C. (ambient temperature), or by considering a predefined temperature range using a gradient between one or more hot spots and the remainder of the structure. For example, the hot spots may be the semiconductor components considered at a predefined temperature, for example at 175° C. (their usual operating temperature).

The mechanical stress T results at least in part from different CTEs between the conductor 302 carrying the attachment groove 404 and the overmolding 310.

Moreover, each attachment groove 404 has a length Lo and a width La perpendicular to its length Lo and taken on the upper face 304, i.e. in the continuity of the latter. The width La is preferably at most 5% of its length Lo, and more preferably at most 3%.

The attachment groove 404 is preferably placed in such a way that the point P through which it passes is substantially in the middle thereof, for example between 40% and 60% of the length Lo.

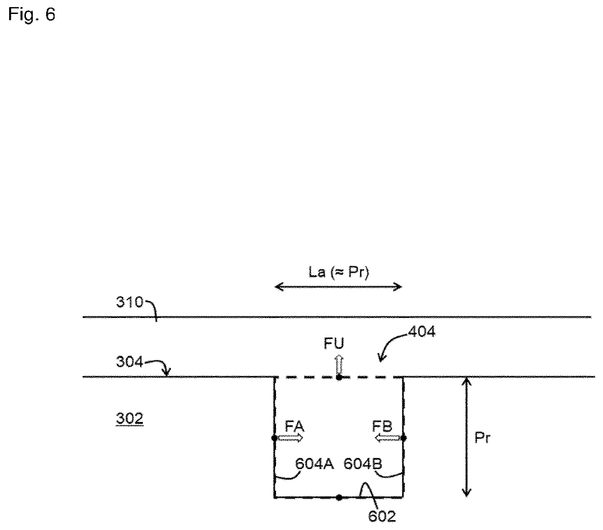

With reference to FIG. 6, each attachment groove 404 has a bottom 602, i.e. the portion of the attachment groove 404 furthest from the upper face 304. Each attachment groove 404 also has two side walls 604A, 604B extending from the bottom 602 to the upper face 304.

Moreover, each attachment groove 404 has a depth Pr (distance between the bottom 602 and the upper face 304) substantially equal to its width La. For example, the width La is between 90% and 110% of the depth Pr.

For example, the two side walls 604A, 604B are perpendicular to the upper face 304.

According to a simple model of the forces applied to the portion of the overmolding 310 present in the attachment groove 404 (this portion being marked by dotted lines), this portion of the overmolding 310 is subjected to two lateral forces FA, FB from the side walls 604A, 604B and a detachment force FU at the top of the attachment groove 404. Considering this simple model, a detachment occurs when the detachment force FU becomes greater than the sum of the two friction forces against the two side walls 604A, 604B, i.e. when the detachment force FU becomes greater than f×FA+f×FB=f×FC, where FC=FA+FB and f is the coefficient of friction between the overmolding 310 and the side walls 604A, 604B and assumed to be identical for the two walls 604A, 604B. Thus, the detachment threshold is f×FC.

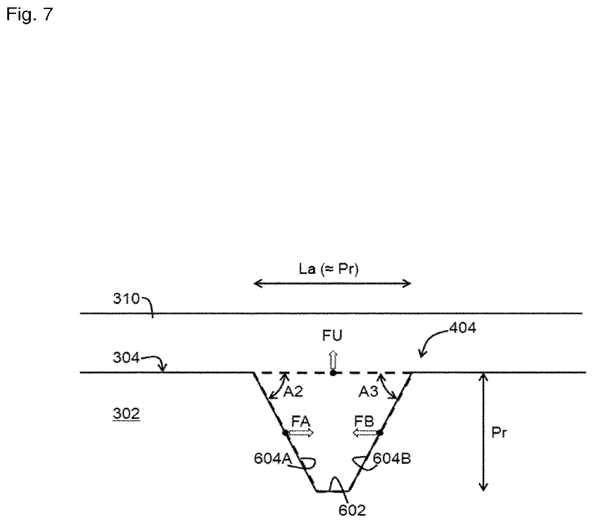

With reference to FIG. 7, alternatively, the two side walls 604A, 604B are oblique with respect to the upper face 304. Preferably, each of the side walls 604A, 604B forms, with the upper face 304, an angle A2 or A3 respectively of between 30° and 60° with the upper face (FS). The two angles A2, A3 are for example equal.

These angles A2, A3 are measured in the attachment groove 404, as illustrated.

Using the same simple model as in FIG. 6, the detachment threshold with the two oblique side walls 604A, 604B having the same angle A=A2=A3 is f×cos²(A)×FC.

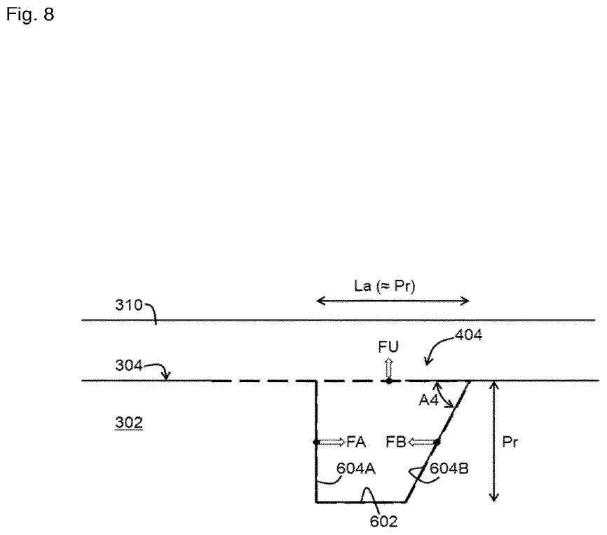

With reference to FIG. 8, alternatively, one side wall 604A of the side walls 604A, 604B is perpendicular to the upper face 304 and the other side wall 604B is oblique with respect to the upper face 304.

Preferably, the oblique side wall 604B forms, with the upper face 304, an angle A4 of between 30° and 60° with the upper face (FS). The angle A4 is taken in the attachment groove 404, as shown.

Using the same simple model as in FIG. 6, the detachment threshold with one side wall 604A perpendicular and the other side wall 604B oblique, is 0.5×fx (1+cos²(A4)×FC.

Thus, the detachment threshold may be higher for the embodiment in FIG. 8, compared with the embodiments in FIGS. 6 and 7.

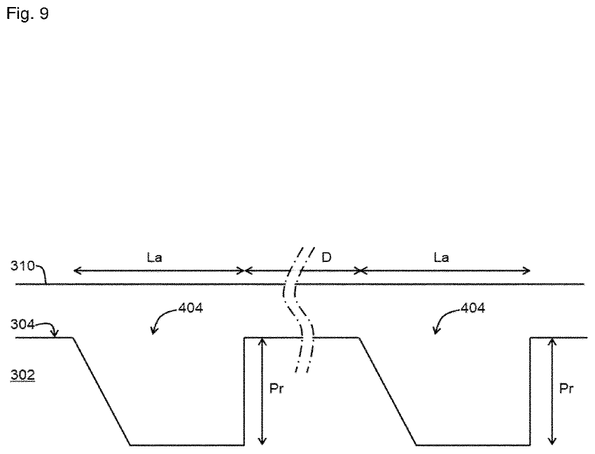

With reference to FIG. 9, two parallel attachment grooves 404 are preferably separated from each other by a distance D greater than five times the depth Pr and/or the width La of each of the two.

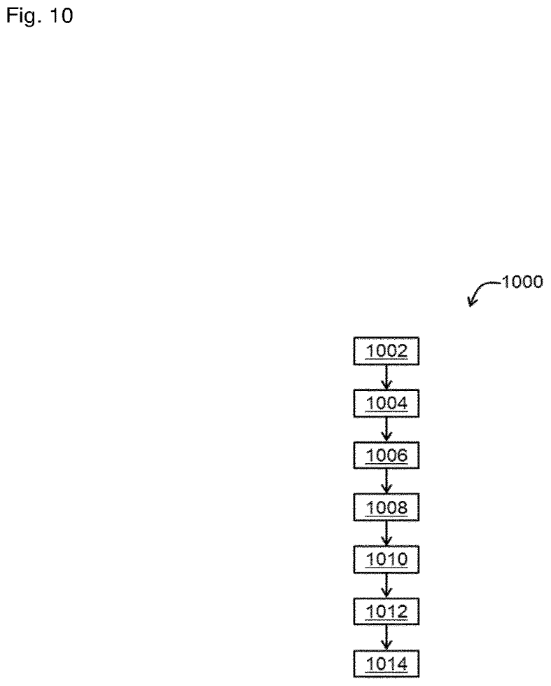

An example of a method 1000 according to the invention for manufacturing a power module 300 from the preceding figures is described below with reference to FIG. 10.

An initial plate is obtained during a step 1002. The plate is for example made of copper and for example has a thickness greater than 1 mm.

During a step 1004, an evaluation is made, in the power module 300 to be manufactured, of a mechanical stress T exerted by the overmolding 310 at each of several points P on at least one of the upper faces 304 of the conductors 302. This evaluation is carried out for example by numerical simulation or by measurements on a test power module, identical to the one to be manufactured, in both cases without attachment grooves. Indeed, the presence of attachment grooves does not substantially change the stresses exerted by the overmolding 310 on the surfaces 314.

For example, isostress lines are determined and the mechanical stresses T at several points P on each of them are evaluated.

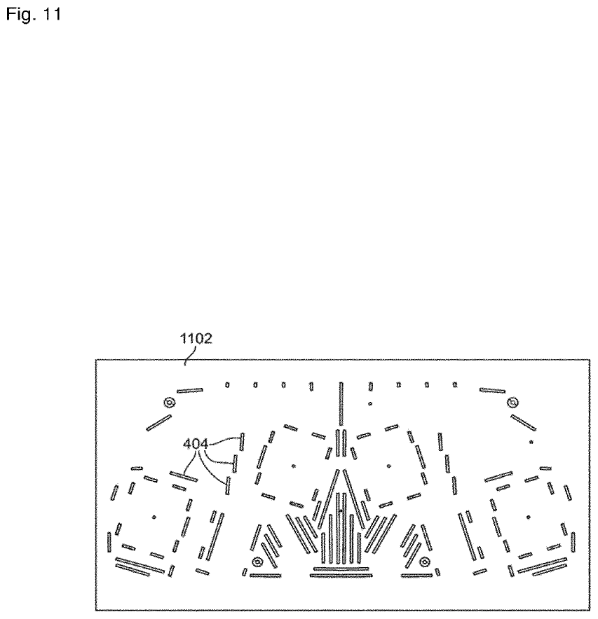

During a step 1006, the result of which is illustrated in FIG. 11, the confinement grooves 402 and the attachment grooves 404 are made on the plate, denoted by reference sign 1102. In particular, the attachment grooves 404 are placed on the points P respectively, forming, at the associated point P, an angle with the evaluated mechanical stress T of between 60° and 120°, preferably between 85° and 95°, and more preferably 90°. Thus, several grooves may be provided along one isostress line.

The confinement grooves 402 and/or attachment grooves 404 are for example made by stamping the initial plate. As the plate has not yet been cut, it is easy to position the counter-supports for stamping.

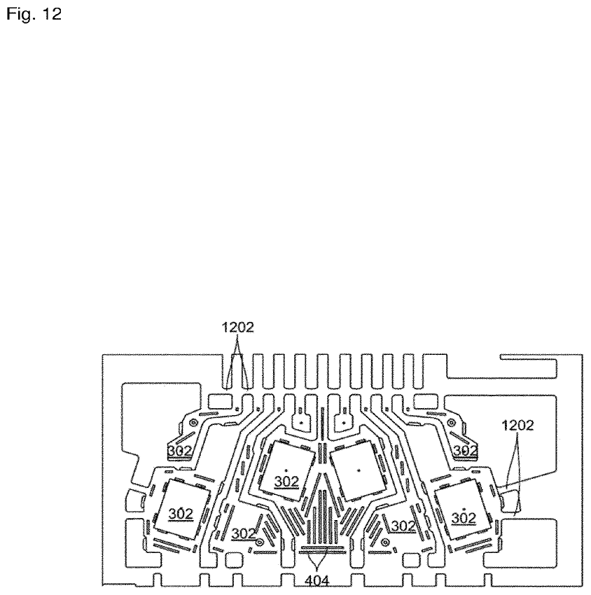

Returning to FIG. 10, during a step 1008, the result of which is illustrated in FIG. 12, the plate is cut to obtain the conductors 302, with retaining tabs 1202 (only some are referenced in FIG. 12, for the sake of clarity).

Returning to FIG. 10, during a step 1010, the semiconductor components 306 are each fastened to an upper face 304 of one of the conductors 302, and the wirings 308 are made.

During a step 1012, the overmolding 310 is made to cover, in the example described here, the conductors 302 and their wirings 308, as well as the attachment grooves 404, so as to fill the latter.

For example, the cut plate, with the semiconductor components 306 and the wirings 308 are heated. The conductors 302 then expand according to their CTE.

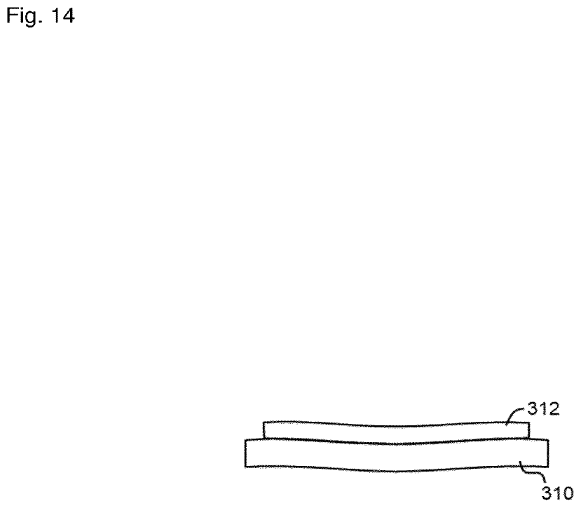

The assembly is then placed into a preheated mold, into which epoxy resin at a temperature above 150° C., for example 175° C., is injected. The epoxy resin then begins to cross-link and contracts (volume shrinkage effect) resulting in a slight downward bowing, for example of a few hundredths of a millimeter. The result is illustrated in FIG. 14.

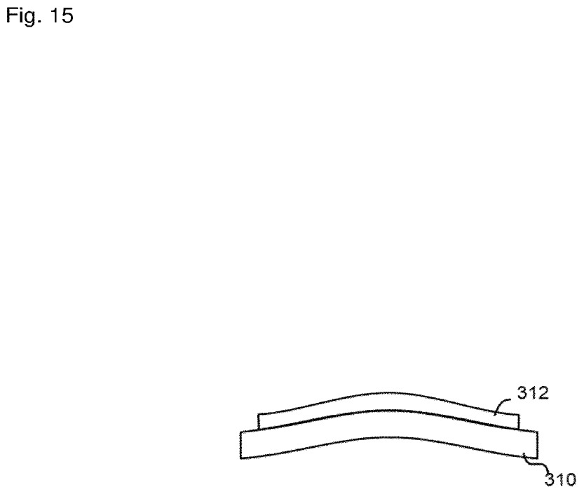

The assembly is then removed from the mold and cooled to ambient temperature to complete the cross-linking. This cooling is accompanied by a contraction of the conductors 302 and the overmolding 310, to different extents on account of their different CTEs. These new stresses result in an upward bowing, much greater than the downward bowing due to the cross-linking of the epoxy resin. The result is illustrated in FIG. 15.

Thus, the risk of detachment is mainly due to this upward bowing and therefore to the different CTEs. This risk is nevertheless greatly reduced by the presence of the attachment grooves 404.

During a separation step 1014, the retaining tabs are cut out.

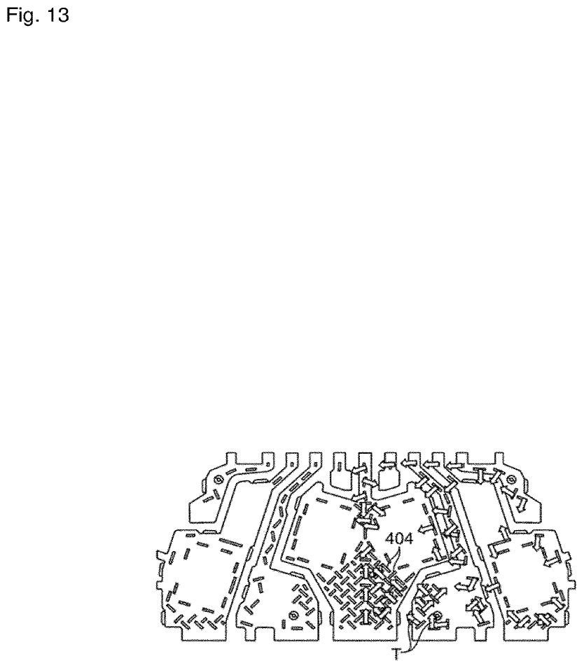

With reference to FIG. 13, in some embodiments, the attachment grooves 404 may be arranged perpendicular to each other. This prevents the overmolding 310 from sliding along the attachment grooves 404.

In conclusion, it will be noted that the invention is not limited to the embodiments described above. Specifically, it will be obvious to a person skilled in the art that various modifications may be made to the embodiments described above, in light of the teaching that has just been disclosed to them.

In the detailed presentation of the invention that was given above, the terms that were used must not be understood as limiting the invention to the embodiments disclosed in the present description, but must be understood as including all equivalents, the anticipation of which is within the scope of a person skilled in the art applying their general knowledge to the implementation of the teaching that has just been disclosed to them.

1. A power module (300) including:
electrical conductors each having an upper face
at least one semiconductor component fastened to the upper face of one of the conductors-(302); and
an overmolding extending over at least a portion of the upper face of each of the conductors
wherein at least one of the upper faces has, in its overmolded portion, at least one attachment groove which is filled by the overmolding and passes through a point (P) on the upper face that is subjected to a mechanical stress (T) by the overmolding the attachment groove forming, at this point (P), at a predefined temperature, an angle with the mechanical stress (T) of between 60° and 120°, preferably between 85° and 95°, and more preferably 90°.

2. The power module as claimed in claim 1, wherein the mechanical stress (T) results at least in part from the different coefficients of thermal expansion of the conductor carrying the attachment groove and the overmolding

3. The power module as claimed in claim 1, wherein the attachment groove is located at least 0.3 mm from the semiconductor component or components

4. The power module as claimed in claim 1, wherein the attachment groove is straight.

5. The power module as claimed in claim 1, wherein the attachment groove has a length (Lo) and a width (La) perpendicular to its length (Lo) of at most 5% of its length (Lo).

6. The power module as claimed in claim 1, wherein the attachment groove has a bottom and two side walls extending from the bottom to the upper face of the conductor carrying the attachment groove the two side walls being perpendicular to the upper face.

7. The power module as claimed in claim 1, wherein the attachment groove has a bottom and two side walls extending from the bottom to the upper face of the conductor carrying the attachment groove one side wall of the side walls being perpendicular to the upper face and the other side wall being oblique with respect to the upper face.

8. The power module as claimed in cclaim 1, wherein the attachment groove has a bottom and two side walls extending from the bottom to the upper face of the conductor carrying the attachment groove the two side walls being oblique with respect to the upper face.

9. The power module as claimed in claim 7, wherein the oblique side wall or the oblique side walls form, with the upper face, an angle (A4) of between 30° and 60° with the upper face

10. The power module as claimed in claim 1, including two parallel attachment grooves on the upper face of one electrical conductor without any other attachment grooves between them.

11. The power module as claimed in claim 10, wherein each of the two parallel attachment grooves has a depth (P) and a width (L) on the upper face these two parallel attachment grooves being separated from each other by a distance greater than five times the depth (P) and/or the width (L) of each of the two.

12. The power module as claimed in claim 1, including two attachment grooves on the upper face of one electrical conductor perpendicular to each other.

13. A voltage converter including at least one power module as claimed in claim 1, and a system for controlling the semiconductor component or components of the power module or modules.

14. An electric drive device including a voltage converter as claimed in claim 13, designed to perform AC-DC power conversion, and an electric machine connected to the voltage converter.

15. A mobility vehicle including a power module as claimed in claim 1.

16. A method for manufacturing a power module with electrical conductors of which each has an upper face at least one semiconductor component fastened to the upper face of one of the conductors and an overmolding that extends over at least a portion of the upper face of each of the conductors the method including:
evaluating, in the power module to be manufactured, a mechanical stress (T) exerted by the overmolding at a point (P) on the upper face of one of the conductors;
making at least one attachment groove on the upper face the attachment groove passing through the point (P) where the mechanical stress (T) has been evaluated and forming at this point (P) an angle (A1) with the mechanical stress (T) of between 60° and 120°, preferably between 85° and 95°;
fastening the semiconductor component or components to the upper face of one of the conductors; and
overmolding the conductors and in particular at least a portion of the upper face where the attachment groove has been made, so as to fill the attachment groove with the overmolding.

17. The power module as claimed in claim 2, wherein the attachment groove is located at least 0.3 mm from the semiconductor component or components.

18. The power module as claimed in claim 2, wherein the attachment groove is straight.

19. The power module as claimed in claim 2, wherein the attachment groove has a length (Lo) and a width (La) perpendicular to its length (Lo) of at most 5% of its length (Lo).

20. The power module as claimed in claim 2, wherein the attachment groove has a bottom and two side walls extending from the bottom to the upper face of the conductor carrying the attachment groove, the two side walls being perpendicular to the upper face.
